(19) United States
(12) Patent Application Publication
(10) Pub. No.: US 2026/0231512 A1
(43) Pub. Date: Aug. 6, 2026

(54) SEMICONDUCTOR DEVICE

(71) Applicant: Minebea Power Semiconductor Device Inc., Ibaraki (JP)

(72) Inventors: Masaki SHIRAISHI, Hitachi-shi (JP); Masaki NAMAI, Hitachi-shi (JP); Tomoyasu FURUKAWA, Tokyo (JP); Yujiro TAKEUCHI, Tokyo (JP)

(21) Appl. No.: 19/123,840

(22) PCT Filed: Sep. 27, 2023
(86) PCT No.: PCT/JP2023/035177

§ 371 Date: Apr. 24, 2025

(30) Foreign Application Priority Data
Nov. 22, 2022 (JP) 2022-186497

(51) Int. Cl. H10D 84/00; H10D 8/00; H10D 12/00

(52) U.S. Cl. CPC H10D 84/161; H10D 8/00; H10D 12/481

(57) ABSTRACT

A semiconductor device can prevent element breakage during diode recovery. The semiconductor device includes an IGBT region with an IGBT having a drift layer of a first conductivity type, a body layer of a second conductivity type, and a first contact layer of the second conductivity type, which has an impurity concentration higher than that of the body layer. A diode region includes a diode having a first semiconductor layer of the second conductivity type and a second contact layer of the second conductivity type, which has an impurity concentration higher than that of the first semiconductor layer. An area of the second contact layer of the diode in a boundary portion vicinity close to a boundary portion between the IGBT region and the diode region is smaller than an area of the second contact layer of the diode in a position far from the boundary portion vicinity.

### TECHNICAL FIELD

The present invention relates to a semiconductor device.

### BACKGROUND ART

A reverse-conducting insulated gate bipolar transistor (RC-IGBT) obtained by incorporating an IGBT and a diode within the same chip has an advantage in that a termination region can be shared between the IGBT and the diode, making it possible to reduce the chip size. In addition, since the IGBT and the diode operate at different timings, heat caused by loss generated in one of the IGBT region and the diode region is dispersed to the other region, allowing the heat to be dissipated throughout the chip, and as a result, it is also possible to reduce thermal resistance.

On the other hand, in the RC-IGBT, carriers (holes) tend to flow from the diode region to the IGBT region at the time of diode recovery, which is the timing at which the IGBT turns ON and the diode changes from conduction to non-conduction, and as a result, a problem occurs in that the carriers (holes) become concentrated in a boundary portion between the diode region and the IGBT region, causing element breakage.

As a semiconductor device that reduces element breakage of this type, FIG. 9 of Patent Literature 1, for example, illustrates a structure in which a p+-type contact layer (14) is not provided in the IGBT region closest to the boundary between the IGBT region (10) and the diode region (20), surfaces of an n+-type source layer (13) and a p-type base layer (15) constitute a first main surface of a semiconductor substrate, and the nt-type source layer (13) is in contact with an active trench gate (11) but not in contact with a boundary trench gate (51).

### CITATION LIST

### Patent Literature

Patent Literature 1: Japanese Patent Application Publication No. 2022-25674

### SUMMARY OF INVENTION

### Technical Problem

However, when the p+-type contact layer (14) is not provided in the IGBT region at the boundary portion, as in Patent Literature 1, holes are less likely to flow through the IGBT at the boundary portion during an operation of the IGBT, and as a result, problems such as an increase in the ON voltage and an increase in the likelihood of the IGBT becoming latched up may arise.

The problem to be solved by the present invention is to provide a semiconductor device that has an IGBT region and a diode region in the same chip, and that can prevent carriers from flowing to the IGBT region from the diode region so as to become concentrated in a boundary portion, thereby causing element breakage, during diode recovery.

### Solution to Problem

In order to solve the above problem, for example, a semiconductor device of the present invention is a semiconductor device having an IGBT region and a diode region in the same chip, wherein an IGBT in the IGBT region has a drift layer of a first conductivity type, a body layer of a second conductivity type, a first contact layer of the second conductivity type, which is connected to the body layer and has an impurity concentration higher than that of the body layer, and an emitter electrode connected to the first contact layer, a diode in the diode region has a first semiconductor layer of the second conductivity type, a second contact layer of the second conductivity type, which is connected to the first semiconductor layer and has an impurity concentration higher than that of the first semiconductor layer, and a first electrode connected to the second contact layer and the emitter electrode, and an area of the second contact layer of the diode in a boundary portion vicinity close to a boundary portion between the IGBT region and the diode region is smaller than an area of the second contact layer of the diode in a position far from the boundary portion vicinity.

### Advantageous Effects of Invention

According to the present invention, in a semiconductor device having an IGBT region and a diode region in the same chip, it is possible to prevent carriers from flowing to the IGBT region from the diode region so as to become concentrated in a boundary portion, thereby causing element breakage, during diode recovery.

### BRIEF DESCRIPTION OF DRAWINGS

FIG. 1 is a perspective view illustrating a schematic configuration of a semiconductor device of embodiment 1.

FIG. 2 is an upper view of the semiconductor device of embodiment 1.

FIG. 3 is an upper view of a semiconductor device of embodiment 2.

FIG. 4 is an upper view of a semiconductor device of embodiment 3.

### DESCRIPTION OF EMBODIMENTS

Embodiments of the present invention will be described below using the drawings. In each drawing and each embodiment, identical or similar constituent elements have been allocated identical reference symbols, and duplicate description thereof has been omitted.

### Embodiment 1

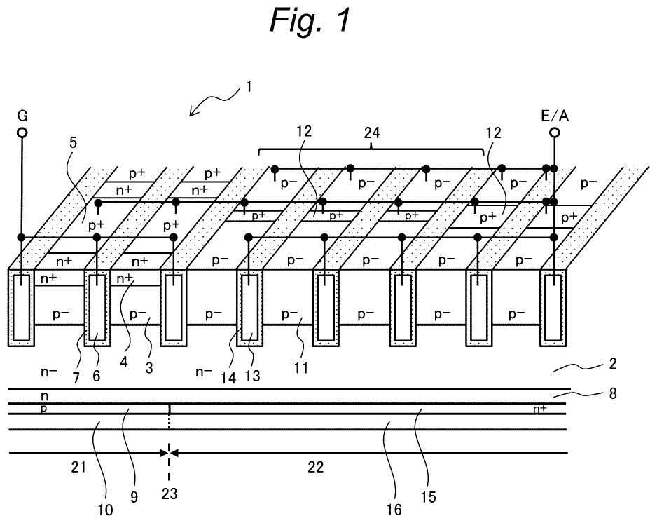

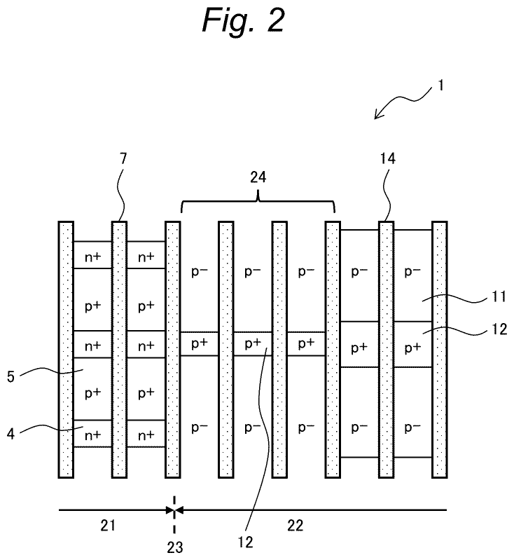

FIG. 1 is a perspective view illustrating a schematic configuration of a semiconductor device of embodiment 1. FIG. 2 is an upper view of the semiconductor device of embodiment 1.

As shown in FIG. 1, a semiconductor device 1 is an RC-IGBT having an IGBT region 21 and a diode region 22 in the same chip.

An IGBT in the IGBT region 21 has a drift layer 2 of a first conductivity type (the n-type in FIG. 1), a body layer 3 of a second conductivity type (the p-type in FIG. 1), a first contact layer 5 of the second conductivity type, which is connected to the body layer 3 and has an impurity concentration higher than that of the body layer 3, and an emitter electrode (not shown) connected to the first contact layer 5. As will be described later, the conductivity types of the semiconductor layers are not limited to the example shown in FIG. 1, and the n-type and the p-type may be switched. Further, as will be described later, impurity concentrations such as n− and p+ are also examples, and can be changed as appropriate within a range in which a desired operation can be performed.

The IGBT in the IGBT region 21 also includes a trench gate 6, a gate insulating film 7, an emitter layer 4 of the first conductivity type, connected to the body layer 3, a collector layer 9 of the second conductivity type, provided further toward a rear surface side than the drift layer 2, and a collector electrode 10 connected to the collector layer 9. The collector electrode 10 is also connected to a second electrode 16 of the diode region 22, to be described later. Furthermore, the IGBT in the IGBT region 21 preferably includes a buffer layer 8 of the first conductivity type, which is provided between the drift layer 2 and the collector layer 9 and has an impurity concentration higher than that of the drift layer 2.

The trench gate 6 and the gate insulating film 7 are formed in a trench that penetrates the body layer 3 and reaches the drift layer 2. the trench gate 6 is formed from polysilicon, for example. A gate potential G is applied to the trench gate 6.

The first contact layer 5 is in ohmic contact with the emitter electrode (not shown) through a contact hole formed in an interlayer insulating film (not shown). An emitter potential E is applied to the first contact layer 5. Further, the emitter layer 4 is either in ohmic contact with the emitter electrode (not shown) through a contact hole formed in the interlayer insulating film (not shown) or connected to the emitter electrode (not shown) through the first contact layer 5.

A diode in the diode region 22 has a first semiconductor layer 11 of the second conductivity type, a second contact layer 12 of the second conductivity type, which is connected to the first semiconductor layer 11 and has an impurity concentration higher than that of the first semiconductor layer 11, and a first electrode (not shown) connected to the second contact layer 12 and the emitter electrode (not shown).

The diode in the diode region 22 also includes the drift layer 2, which is provided further toward the rear surface side than the first semiconductor layer 11, a second semiconductor layer 15 of the first conductivity type, which is provided further toward the rear surface side than the drift layer 2 and has an impurity concentration higher than that of the drift layer 2, and the second electrode 16, which is connected to the second semiconductor layer 15.

Here, when the first conductivity type is the n-type and the second conductivity type is the p-type, as shown in FIG. 1, the first semiconductor layer 11 is an anode layer, the first electrode (not shown) is an anode electrode, the second semiconductor layer 15 is a cathode layer, and the second electrode 16 is a cathode electrode.

In the diode region 22, no interlayer insulating film is formed, the high-concentration second contact layer 12 is in ohmic contact with the first electrode (not shown), and an anode potential A having the same potential as the emitter potential E is applied to the second contact layer 12. Furthermore, the low-concentration first semiconductor layer 11 forms a Schottky junction with the first electrode (not shown).

Note that when the first conductivity type is the p-type and the second conductivity type is the n-type, the first semiconductor layer 11 is a cathode layer, the first electrode (not shown) is a cathode electrode, the second semiconductor layer 15 is an anode layer, and the second electrode 16 is an anode electrode.

Furthermore, the buffer layer 8 is preferably also formed in the diode region 22.

A trench that penetrates the first semiconductor layer 11 and reaches the drift layer 2 is preferably also formed in the diode region 22, and a diode region trench electrode 13 and a diode region trench insulating film 14 are preferably formed in the trench. The diode region trench electrode 13 is formed from polysilicon, for example. The anode potential A having the same potential as the emitter potential E is preferably applied to the diode region trench electrode 13.

In the semiconductor device 1 of this embodiment, the amount of carriers (holes in a case where the first conductivity type is the n-type and the second conductivity type is the p-type, as shown in FIG. 1) injected when the diode is conductive can be controlled by the ratio between the high-concentration second contact layer 12 and the low-concentration first semiconductor layer 11 formed on the surface. When the second contact layer 12 is large, many carriers can be injected, and when the first semiconductor layer 11 is large, carrier

Hence, in the semiconductor device 1 of this embodiment, the area of the second contact layer 12 of the diode in a boundary portion vicinity 24 near a boundary portion 23 between the IGBT region 21 and the diode region 22 is set to be smaller than the area of the second contact layer 12 of the diode in a position far from the boundary portion vicinity 24. Thus, the carrier injection amount when the diode is conductive in the boundary portion vicinity 24 becomes smaller than the carrier injection amount of the diode in a position far from the boundary portion vicinity 24, whereby the carrier injection amount can be suppressed even when the carriers in the boundary portion vicinity 24 flow to the side of the IGBT region 21 at the time of diode recovery, and as a result, it is possible to prevent element breakage due to carriers flowing to the IGBT region 21 from the diode region 22 so as to become concentrated at the boundary portion 23 during recovery of the diode.

Note that in FIG. 1, the drift layer 2 is shown to be of the low-concentration n− type, the body layer 3 and the first semiconductor layer 11 are shown to be of the low-concentration p− type, the emitter layer 4 and the second semiconductor layer 15 are shown to be of the high-concentration nt type, the first contact layer 5 and the second contact layer 12 are shown to be of the high-concentration p+-type, and the other components are shown to be of the n-type or the p-type, but the components are not limited thereto and can be modified as appropriate within a range in which the desired operation can be performed.

Furthermore, when the first conductivity type is the p-type and the second conductivity type is the n-type, electrons rather than holes serve as the carriers, and therefore the word “hole” should be replaced with the word “electron” in relation to the carriers.

### Embodiment 2

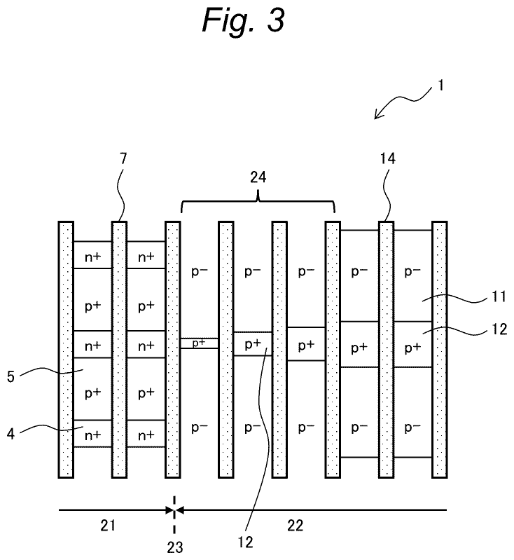

FIG. 3 is an upper view of a semiconductor device of embodiment 2.

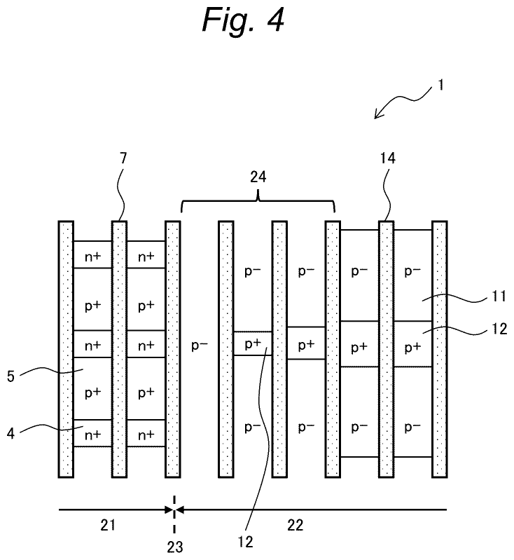

Embodiment 2 is a modification of embodiment 1. The semiconductor device 1 of this embodiment differs from embodiment 1 in that the area of the second contact layer 12 in the boundary portion vicinity 24 gradually decreases toward the boundary portion 23. Thus, carriers can be injected to a certain extent in a part of the boundary portion vicinity 24 away from the boundary portion 23 in order to lower the forward voltage while preventing the carriers from becoming concentrated at the boundary portion 23. Other effects are the same as those of embodiment 1, and therefore description thereof has been FIG. 4 is an upper view of a semiconductor device of embodiment 3.

Embodiment 3 is a modification of embodiment 2. The semiconductor device 1 of this embodiment differs from embodiment 2 in that the second contact layer 12 is not provided in the region of the diode region 22 that is in contact with the boundary portion 23. As a result, the effect of suppressing carrier concentration at the boundary portion 23 while injecting carriers to a certain extent in a part of the boundary portion vicinity 24 away from the boundary portion 23 in order to lower the forward voltage, similarly to embodiment 2, can be enhanced in comparison with embodiment 2. Other effects are the same as those of embodiment 2, and therefore description thereof has been omitted.

The configuration of embodiment 3 may also be applied to embodiment 1. In this case, the effect of lowering the forward voltage is weaker than in embodiment 2, but the effect of suppressing carrier concentration at the boundary portion 23 can be enhanced in comparison with embodiment 1.

Although embodiments of the present invention were described above, the present invention is not limited to the configurations described in the embodiments, and various modifications are possible within the scope of the technical concept of the present invention. In addition, some or all of the configurations described in the embodiments may be applied in combination.

### REFERENCE SIGNS LIST

1 Semiconductor device
2 Drift layer
3 Body layer
4 Emitter layer
5 First contact layer
6 Trench gate
7 Gate insulating film
8 Buffer layer
9 Collector layer
10 Collector electrode
11 First semiconductor layer
12 Second contact layer
13 Diode region trench electrode
14 Diode region trench insulating film
15 Second semiconductor layer
22 Diode region
23 Boundary portion
24 Boundary portion vicinity
G Gate potential
E Emitter potential
A Anode potential

1. A semiconductor device having an IGBT region and a diode region in the same chip,
wherein an IGBT in the IGBT region has a drift layer of a first conductivity type, a body layer of a second conductivity type, a first contact layer of the second conductivity type, which is connected to the body layer and has an impurity concentration higher than that of the body layer, and an emitter electrode connected to the first contact layer,
a diode in the diode region has a first semiconductor layer of the second conductivity type, a second contact layer of the second conductivity type, which is connected to the first semiconductor layer and has an impurity concentration higher than that of the first semiconductor layer, and a first electrode connected to the second contact layer and the emitter electrode, and
an area of the second contact layer of the diode in a boundary portion vicinity close to a boundary portion between the IGBT region and the diode region is smaller than an area of the second contact layer of the diode in a position far from the boundary portion vicinity.

2. The semiconductor device according to claim 1,
wherein the area of the second contact layer in the boundary portion vicinity gradually decreases toward the boundary portion.

3. The semiconductor device according to claim 1,
wherein the second contact layer is not provided in a region of the diode region that is in contact with the boundary portion.

4. The semiconductor device according to claim 1,
wherein the diode includes the drift layer, which is provided further toward a rear surface side than the first semiconductor layer, a second semiconductor layer of the first conductivity type, which is provided further toward the rear surface side than the drift layer and has an impurity concentration higher than that of the drift layer, and a second electrode connected to the second semiconductor layer.

5. The semiconductor device according to claim 4,
wherein the IGBT includes a trench gate, a gate insulating film, an emitter layer of the first conductivity type, connected to the body layer, a collector layer of the second conductivity type, provided further toward the rear surface side than the drift layer, and a collector electrode connected to the

6. The semiconductor device according to claim 5,
having a buffer layer of the first conductivity type, which is provided between the drift layer and the collector layer and has an impurity concentration higher than that of the drift layer.

7. The semiconductor device according to claim 1,
wherein the first conductivity type is an n-type, the second conductivity type is a p-type, the first semiconductor layer is an anode layer, and the first electrode is an anode electrode.
